(19) United States
(12) Patent Application Publication
(10) Pub. No.: US 2010/0074456 A1
(43) Pub. Date: Mar. 25, 2010

(54) SYSTEM FOR ADJUSTING PLAYING VOLUME ACCORDING TO PREDETERMINED TIME AND METHOD FOR THE SAME

(76) Inventor: Shiun-Chih Liao, Taichung City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 12/235,939

(22) Filed: Sep. 23, 2008

(51) Int. Cl. H03G 3/00

(52) U.S. Cl. 381/107

(57) ABSTRACT

A system for adjusting playing volume according to a predetermined time and a method for the same are provided. The system includes a time data unit, a volume adjustment database, a volume control unit, and an audio frequency module. The time data unit generates a current time data. The volume adjustment database is built-in and configured to store an audio variation data. The audio frequency module receives and outputs an audio frequency signal. By reference to the current time data and the audio variation data, the volume control unit adjusts variation of the audio frequency signal outputted in real time, thereby enchanting audience and enhancing delivery of advertisement messages.

### BACKGROUND OF THE INVENTION

1. Field of the Invention

The present invention relates to a system for adjusting playing volume and a method for the same, and more particularly, to a system for adjusting playing volume according to a predetermined time and a method for the same.

2. Description of the Prior Art

Ever-changing technology accompanies progress and changes in advertisement. The advertisement industry is innovative not only in contents of advertisements but also in vehicles of advertisement. For instance, existing vehicles of advertisement are, namely flyers, newspaper advertisement, TV advertisement, online advertisement, mobile advertisement, etc. An emerging vehicle of advertisement is an advertisement player for playing advertisement messages in public.

In general, advertisement players are placed at venues with heavy traffic, such as on buses, at department store's elevator doors, or in crowded shopping malls. Passers-by are unwittingly impressed by advertisement messages played by advertisement players installed at specific venues on a long-term basis for ceaseless, iterative delivery of advertisement messages, uninvited and repeated.

Known advertisement players are selectively operated by two different systems. The first system plays advertisement messages with a player and then displays the messages on a liquid crystal display (LCD). The second system sends advertisement messages to a set top box (STB) at a client end by the Internet, transmits the advertisement messages from the STB to the LCD, and plays the advertisement messages received by the LCD.

The latter is flexible and expandable. However, both systems have a vulnerable drawback in common, that is, neither of the systems can provide playing volume that varies with ambient volume. For instance, the level of noise around elevators in department stores varies with the number of elevator users, and thus sometimes the noise can be great enough to drown the playing volume of any advertisement players installed at the elevators; as a result, not only are advertisement messages undelivered, but advertisement messages become inconspicuous. In conclusion, advertisement players of the prior art have the following drawbacks:

1. inconspicuous advertisement messages
2. inefficient delivery of advertisement messages

Hence, the inventor of this application and related manufacturers stand in need of an immediate solution of the aforesaid problems and drawbacks of the prior art.

### SUMMARY OF THE INVENTION

To solve the aforesaid problems, it is a primary objective of the present invention to provide a system for adjusting playing volume according to a predetermined time and a method for the same, wherein a volume control unit adjusts variation of an audio frequency signal outputted in real time according to a current time data generated by a time data unit and an audio variation data stored in a built-in volume adjustment database.

Another objective of the present invention is to provide a system for adjusting playing volume according to a predetermined time, comprising a time data unit for generating a current time data, a volume adjustment database built-in and stored with an audio variation data therein, an audio frequency module for receiving and outputting an audio frequency signal, and a volume control unit for adjusting variation of the audio frequency signal outputted in real time according to the current time data and the audio variation data. The system is efficient in enchanting audience.

Yet another objective of the present invention is to provide a method for adjusting playing volume according to a predetermined time, comprising the steps of: retrieving, by a volume control unit, a current time data generated by a time data unit and an audio variation data stored in a volume adjustment database, respectively; determining, by the volume control unit and according to a result of computation performed on the current time data and the audio variation data, whether playing volume should be currently adjusted, and generating a control signal; and controlling, by the volume control unit and according to the control signal, variation of an audio frequency signal outputted by an audio frequency module in real time. The method is efficient in enchanting audience.

The characteristics and technical features of the present invention will be best understood by reference to the following detailed description of an illustrative embodiment when read in conjunction with the accompanying drawings. The accompanying drawings are only illustrative of the present invention but are not intended to restrict the scope of the present invention.

### BRIEF DESCRIPTION OF THE DRAWINGS

FIG. 1 is a block diagram of a system of the present invention;

FIG. 2 is a block diagram of a loudspeaker unit and a system of the present invention;

FIG. 3 is a block diagram of a loudspeaker unit of a display device and a system of the present invention; and

FIG. 4 is a flow chart of the present invention.

### DETAILED DESCRIPTION OF THE EMBODIMENTS

The objectives, structural features, and functional features of the present invention are illustrated with the preferred embodiments shown in the accompanying drawings.

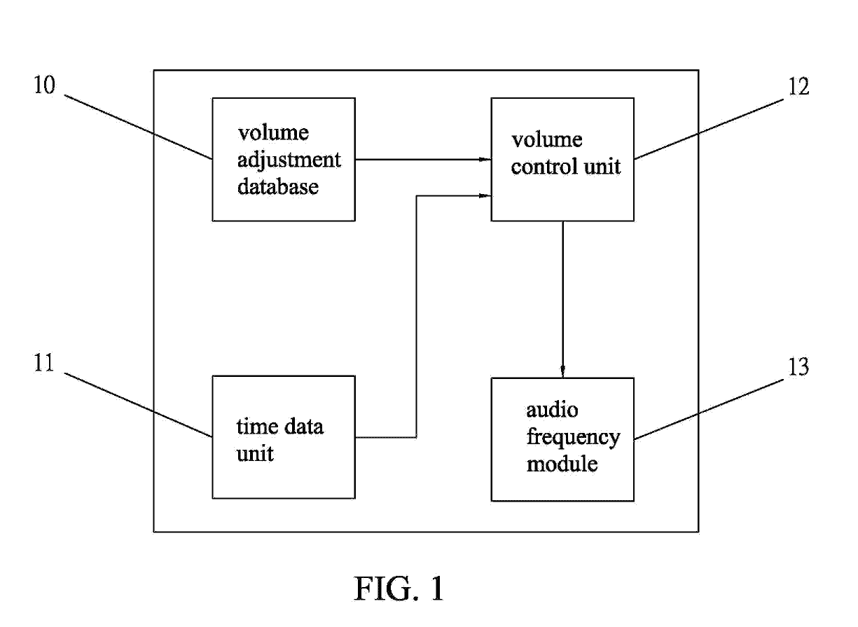

The present invention provides a system for adjusting playing volume according to a predetermined time and a method for the same. Referring to FIG. 1, in a preferred embodiment of the present invention, the system comprises a volume adjustment database 10, a time data unit 11, a volume control unit 12, and an audio frequency module 13. The volume adjustment database 10 is built-in and configured to store an audio variation data therein. The time data unit 11 generates a current time data. The audio frequency module 13 receives an incoming audio frequency signal and outputs the audio frequency signal. The volume control unit 12 retrieves the current time data and the audio variation data and performs computation thereon so as to generate a control signal. Then, the volume control unit 12 adjusts, in real time and according to the control signal, variation of the audio frequency signal outputted by the audio frequency module 13. Hence, the system of the present invention is conducive to enchanting audience and enhancing delivery of advertisement messages. Accordingly, the present invention is effectual in solving known drawbacks of the prior art, namely inconspicuous advertisement messages and inefficient delivery of advertisement messages.

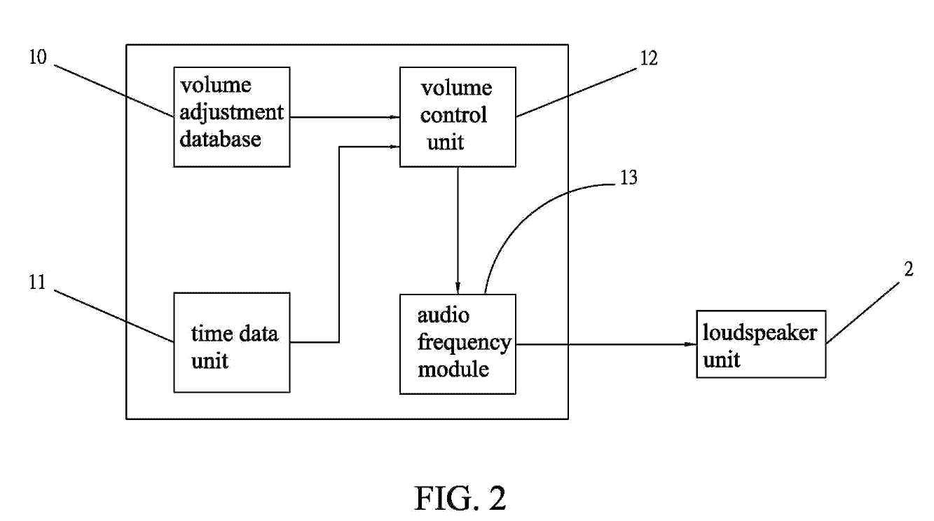

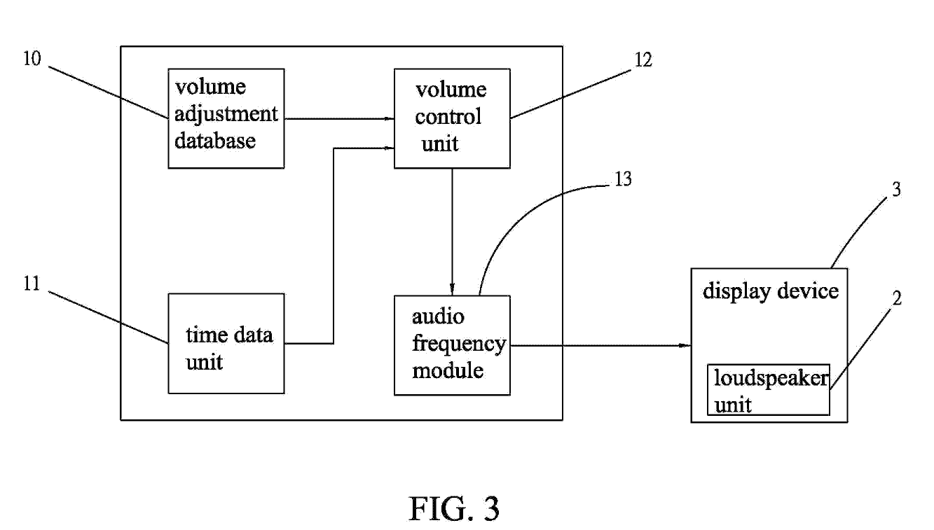

Referring to FIGS. 2 and 3, the audio variation data stored in the volume adjustment database 10 comprises at least a predetermined time and at least a decibel level. The decibel level corresponds to the predetermined time. The predetermined times are equal and/or unequal in decibel level. The predetermined times with equal decibel level are exemplified by 20˜40 decibels at a first predetermined time (8:00˜9:00) and 20˜40 decibels at a second predetermined time (9:00˜10:00). Conversely, the predetermined times with unequal decibel level are exemplified by 30˜50 decibels at a first predetermined time (10:00˜11:00) and 40˜60 decibels at a second predetermined time (11:00˜12:00). In practice, the present invention is not limited to the above disclosures.

The audio frequency module 13 is electrically signal-connected to a loudspeaker unit 2, allowing the audio frequency signal outputted to be played by the loudspeaker unit 2, Increment or decrement of playing volume of the loudspeaker unit 2 corresponds in magnitude to variation of the audio frequency signal. The loudspeaker unit 2 is a loudspeaker.

In addition, the audio frequency module 13 is electrically signal-connected to a display device 3, allowing the audio frequency signal outputted to be played by a loudspeaker unit 2 of the display device 3. Increment or decrement of playing volume of the loudspeaker unit 2 corresponds in magnitude to variation of the audio frequency signal. The display device 3 is a liquid crystal display (LCD) or a plasma display panel.

Furthermore, the system is configured for use with a set top box (STB) device (not shown) so as to control variation of the audio frequency signal outputted by the STB device in real time. The present preferred embodiment is exemplified by a set top box (STB), though, in practice, the present invention is not limited to the above disclosures.

The present invention is illustrated with an exemplification as follows:

Where an advertisement agent installs the STB at a venue fit for delivery of advertisement messages, such as the entrance to or elevator doors in a department store, and applies the system of the present invention to the STB, the advertisement agent may set playing volume level (the decibel level) for each period of time (the predetermined time) in light of volume of shopper traffic during each period of time. In the present preferred embodiment, the decibel level is set for each predetermined time in the morning, at noon, and in the evening. For instance, the decibel level is set to 10˜20 decibels for 10:00˜13:00 in the morning, 20˜30 decibels for 13:00˜16:00 at noon and in the afternoon, 30˜40 decibels for 16:00˜19:00 in the late afternoon, and 40˜60 decibels for 19:00˜22:00 in the evening. In practice, the present invention is not limited to the above disclosures.

If it is currently 12:00 at noon, the volume control unit 12 will retrieve the current time data (12:00), the predetermined time (10:00˜13:00) for the audio variation data, and the decibel level (10˜20 decibels), perform computation thereon, and generate a control signal. Then, by reference to the control signal, the volume control unit 12 controls the audio frequency signal sent to the loudspeaker unit 2 of the display device 3 from the audio frequency module 13. The level of volume (10˜20 decibels) played by the loudspeaker unit 2 of the display device 3 varies with variation of the audio frequency signal received. Hence, the level of volume played is always appropriate at any time, so as to enchant audience and enhance delivery of advertisement messages.

Also, if it is currently 20:00 in the evening, the volume control unit 12 will retrieve the current time data (20:00), the predetermined time (19:00˜22:00) for the audio variation data, and the decibel level (40˜60 decibels), perform computation thereon, and generate a control signal. Then, by reference to the control signal, the volume control unit 12 controls the audio frequency signal sent to the loudspeaker unit 2 of the display device 3 from the audio frequency module 13. The level of volume (40˜60 decibels) played by the loudspeaker unit 2 of the display device 3 varies with variation of the audio frequency signal received. Hence, the level of volume played is always appropriate at any time, so as to enchant audience and enhance delivery of advertisement messages.

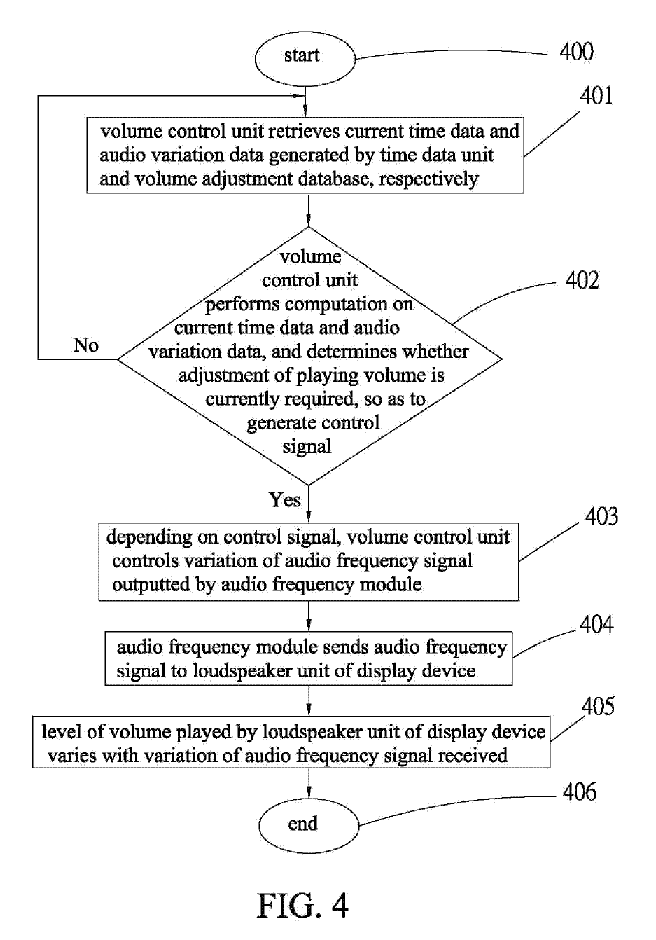

Referring to FIG. 4, in the preferred embodiments of the present invention, playing volume is adjusted according to a predetermined time in the specific steps as follows:
(400) start;
(401) a volume control unit 12 retrieves a current time data generated by a time data unit 11 and an audio variation data stored in a volume adjustment database 10, respectively;
(402) the volume control unit 12 performs computation on the current time data and the audio variation data, and determines whether adjustment of playing volume is currently required, so as to generate a control signal; if the volume control unit 12 determines that the current time data (e.g., 9:00) is not beyond (or between) the predetermined time (set to 8:00˜10:00, for example), the playing volume will not be adjusted, if the volume control unit 12 determines that the current time data (e.g., 11:00) is beyond the predetermined time (set to 8:00˜10:00, for example), the playing volume will be adjusted; in case of affirmative determination, go to step 403; in case of negative determination, go back to step 401;
(403) depending on the control signal, the volume control unit 12 controls variation of the audio frequency signal outputted by an audio frequency module 13;
(404) the audio frequency module 13 sends the audio frequency signal to a loudspeaker unit 2 of a display device 3;
(405) level of volume played by the loudspeaker unit 2 of the display device 3 varies (increases/decreases) with variation of the audio frequency signal received; and
(406) end.

In conclusion, the present invention provides a system for adjusting playing volume according to a predetermined time and a method for the same, which have the following advantages:

1. It enchants audience.
2. It enhances delivery of advertisement messages.

The foregoing preferred embodiments are only illustrative of the features and functions of the present invention but are not intended to restrict the scope of the present invention. It is apparent to those skilled in the art that all equivalent modifications and variations made in the foregoing preferred embodiments according to the spirit and principle in the disclosure of the present invention should fall within the scope of the appended claims.

What is claimed is:

1. A system for adjusting playing volume according to a predetermined time, comprising:
a time data unit for generating a current time data;
a volume adjustment database being built-in and configured for storing an audio variation data;
an audio frequency module for receiving and outputting an audio frequency signal; and
a volume control unit for adjusting variation of the audio frequency signal outputted in real time according to the current time data and the audio variation data.

2. The system for adjusting playing volume according to a predetermined time of claim 1, wherein the audio variation data comprises at least a predetermined time and at least a decibel level corresponding to the predetermined time.

3. The system for adjusting playing volume according to a predetermined time of claim 2, wherein the predetermined times are equal and/or unequal in decibel level.

4. The system for adjusting playing volume according to a predetermined time of claim 1, wherein the audio frequency module is electrically signal-connected to a loudspeaker unit, allowing the audio frequency signal outputted to be played by the loudspeaker unit, wherein increment or decrement of playing volume of the loudspeaker unit corresponds in magnitude to variation of the audio frequency signal.

5. The system for adjusting playing volume according to a predetermined time of claim 1, wherein the audio frequency module is electrically signal-connected to a display device, allowing the audio frequency signal outputted to be played by a loudspeaker unit of the display device, wherein increment or decrement of playing volume of the loudspeaker unit corresponds in magnitude to variation of the audio frequency signal.

6. A set top box (STB) having the system of claim 1.

7. A method for adjusting playing volume according to a predetermined time, comprising the steps of:
retrieving, by a volume control unit, a current time data generated by a time data unit and an audio variation data stored in a volume adjustment database, respectively;
determining, by the volume control unit and according to a result of computation performed on the current time data and the audio variation data, whether playing volume should be currently adjusted, and generating a control signal; and
controlling, by the volume control unit and according to the control signal, variation of an audio frequency signal outputted by an audio frequency module in real time.

8. The method for adjusting playing volume according to a predetermined time of claim 7, wherein the audio variation data comprises at least a predetermined time and at least a decibel level corresponding to the predetermined time.

9. The method for adjusting playing volume according to a predetermined time of claim 8, wherein playing volume is not adjusted upon determination by the volume control unit that the current time data is not beyond the predetermined time.

10. The method for adjusting playing volume according to a predetermined time of claim 8, wherein playing volume is adjusted upon determination by the volume control unit that the current time data is beyond the predetermined time.
